(19) United States
(12) Patent Application Publication
(10) Pub. No.: US 2014/0268518 A1
(43) Pub. Date: Sep. 18, 2014

(54) DURABLE PROTECTIVE BATTERY CASE

(71) Applicant: Mophie, Inc., Tustin, CA (US)

(72) Inventors: Daniel Huang, Irvine, CA (US); Matthew Brand, Brooklyn, NY (US); Nguyen To, Corona, CA (US); Andrew Namminga, Costa Mesa, CA (US)

(73) Assignee: Mophie, Inc., Tustin, CA (US)

(21) Appl. No.: 14/205,024

(22) Filed: Mar. 11, 2014

Related U.S. Application Data
(60) Provisional application No. 61/802,181, filed on Mar. 15, 2013.

(51) Int. Cl. H05K 5/06

(52) U.S. Cl. CPC H05K 5/065
USPC 361/679.01

(57) ABSTRACT

A durable and water-resistant or water-proof communication accessory with a built-in battery for a mobile communication device capable of enclosing, powering, and protecting a mobile device and protecting it from dirt, water, weather, bumps, and scratches. The built-in battery can extend the life of mobile communication device while protecting the sensitive electronics, glass screen, and data.

### CROSS-REFERENCE TO RELATED APPLICATIONS

This application claims the benefit under 35 U.S.C. §119(e) of U.S. Provisional Patent Application No. 61/802,181, filed on Mar. 15, 2013, and titled “DURABLE PROTECTIVE BATTERY CASE.” The above-identified patent application is incorporated by reference in its entirety and made a part of this specification for all that it discloses.

### INCORPORATION BY REFERENCE

The following U.S. patents and patent applications are incorporated by reference in their entirety and made a part of this specification for all that they disclose: U.S. Design Pat. Application No. 29/406,346, titled “MULTI-PIECE CASE,” and filed Nov. 11, 2011; U.S. patent application Ser. No. 12/357,262, titled “BATTERY PACK, HOLSTER, AND EXTENDIBLE PROCESSING AND INTERFACE PLATFORM FOR MOBILE DEVICES,” and filed Jan. 21, 2009, now U.S. Pat. No. 8,367,235; U.S. Provisional Patent Application No. 61/768,538, titled “SWITCH COVER AND EXTERNAL CASE INCORPORATING A SWITCH COVER,” and filed Feb. 25, 2013; and U.S. Provisional Patent Application No. 61/696,139, titled “WIRELESS COMMUNICATION REPEATER ANTENNA FOR A MOBILE DEVICE PERIPHERAL,” and filed Sep. 1, 2012.

### FIELD

Various aspects of this disclosure relate to accessories for mobile devices and, more particularly, to an external protective case for a mobile device, where the external protective case can incorporate a battery pack in a water-resistant, crush-resistant, impact-resistant external shell.

### BACKGROUND

Many mobile devices (e.g., mobile phones, digital assistants, mobile communication devices, handheld computing devices, personal music/video/content players and storage devices) are often powered by battery power sources. Such battery power sources are often housed within the mobile device and may be changed and/or recharged as needed. However, as more powerful mobile devices are designed, these tend to consume power more quickly, thereby shortening the time between charges. This tends to limit the usefulness of the mobile device since the user may need to find a power source to recharge the battery source and wait until it is recharged.

Additionally, such mobile devices are designed to satisfy the needs of a wide array of consumers. For instance, such mobile devices may have somewhat limited processing capabilities (e.g., to extend battery power) and limited input/output capabilities. Consequently, in some cases, users who wish to extend the capabilities of the mobile device to implement various types of solutions are prevented from doing so.

Users frequently attach separate after-market cases to their mobile devices, either as a form of expression or to protect the sensitive electronics, the breakable glass, and the important information inside. Some users have to expose their mobile devices to relatively harsh conditions, such as rain, mud, sand, bumps, and frequent drops. The users frequently opt for protective cases.

### SUMMARY

Various embodiments disclosed herein relate to a protective enclosure for a mobile device with a touch screen. The protective enclosure can include a first rigid case portion and a second rigid case portion that together form a protective shell around the mobile device, revealing the touch screen. The protective enclosure can include a first battery and an internal interface capable of electrically coupling with the mobile device when the mobile device is in the protective enclosure. The protective enclosure can include a water-resistant seal between the first rigid case portion and the second rigid case portion and a flexible sleeve configured to be stretched around the protective shell.

The water-resistant seal can be a first gasket.

The protective enclosure can include a plurality of openings and flexible port covers corresponding to ports and/or buttons on the mobile device.

The protective enclosure can include a second gasket capable of forming a water-tight seal around the touch screen.

The protective enclosure can include a membrane attached to the protective shell disposed in front of the touch screen. An input on one side of the membrane opposite the touch screen can register with the touch screen on the mobile device when the mobile device is in the protective enclosure.

The protective enclosure can include a waterproof microphone port, e.g., electrically coupled to a microphone port built into the mobile device.

The protective enclosure can include an external interface electrically coupled to the internal interface.

The first battery and a second battery in the mobile device can be configured to be charged through the external interface.

The protective enclosure can include a battery information display.

The protective shell can include a third case portion.

The battery can be enclosed within the first case portion.

Various embodiments disclosed herein relate to a water-resistant protective enclosure for a mobile device with a touch screen. The protective enclosure can include a first rigid case portion and a second rigid case portion that together form a protective shell with a plurality of openings corresponding to the ports and/or buttons of the mobile device. The protective shell can reveal the touch screen. The protective enclosure can include a flexible sleeve configured to be stretched around the protective shell, and the flexible sleeve can include flexible port covers capable of sealing the plurality of openings. The protective enclosure can include a membrane attached to the protective shell disposed in front of the touch-screen, through which a tactile input on one side of the membrane can register with the touch screen on the mobile device. The protective enclosure can include a battery, an internal interface capable of electrically coupling with the mobile device when the mobile device is in the protective enclosure, and an external interface electrically coupled to the internal interface. The protective enclosure can include a water-resistant seal between the first rigid case portion and the second rigid case portion.

Various embodiments disclosed herein can relate to a water-resistant protective enclosure for a mobile device with a touch screen. The protective enclosure can include a first case portion and a second case portion that together form a protective shell around the mobile device, revealing the touch screen. The protective enclosure can include a plurality of impact-absorbing regions fixed to the protective shell. The protective enclosure can include a battery and an internal interface capable of electrically coupling with the mobile device when the mobile device is in the protective enclosure. The protective enclosure can include a water-resistant seal between the first rigid case portion and the second rigid case portion.

The water-resistant seal can be a first gasket.

The protective enclosure can include a plurality of openings and flexible port covers corresponding to ports and/or buttons on the mobile device.

The protective enclosure can include a second gasket capable of forming a water-tight seal around the touch-screen.

The protective enclosure can include a membrane attached to the protective shell disposed in front of the touch screen. A tactile input on one side of the membrane can register with the touch screen on the mobile device.

The plurality of impact-absorbing regions can be made of over-molded thermoplastic.

The protective enclosure can include a flexible sleeve configured to be stretched around the protective shell.

The protective enclosure can include an external interface electrically coupled to the internal interface. The external interface can be a different connection type from the internal interface.

The foregoing is a summary and contains simplifications, generalization, and omissions of detail. Those skilled in the art will appreciate that the summary is illustrative only and is not intended to be in any way limiting. Other aspects, features, and advantages of the devices and/or processes and/or other subject matter described herein will become apparent in the teachings set forth herein. The summary is provided to introduce a selection of concepts in a simplified form that are further described below in the Detailed Description. This summary is not intended to identify key features or essential features of any subject matter described herein.

### BRIEF DESCRIPTION OF THE DRAWINGS

The foregoing and other features of the present disclosure will become more fully apparent from the following description, taken in conjunction with the accompanying drawings. Understanding that these drawings depict only some embodiments in accordance with the disclosure and are, therefore, not to be considered limiting of its scope, the disclosure will be described with additional specificity and detail through use of the accompanying drawings.

FIG. 1 illustrates various views of an example embodiment of a protective case for a mobile device.

FIG. 2 illustrates various views of an example embodiment of a protective case and a mobile device.

FIG. 3 illustrates cross-sectional views of an example embodiment of a protective case and a mobile device.

FIG. 4 illustrates an exploded perspective view of an example embodiment of a protective case and a mobile device.

FIG. 5 illustrates an exploded perspective view of an example embodiment of a protective case and a mobile device.

FIG. 6 illustrates an exploded perspective view of an example embodiment of a protective case and a mobile device.

FIG. 7 illustrates an example embodiment of a belt clip and protective case for a mobile device.

FIG. 8 illustrates an example embodiment of a belt clip and protective case with a mobile device.

FIG. 9 illustrates an example embodiment of a belt clip and protective case for a mobile device.

FIG. 10 illustrates an example embodiment of a belt clip and protective case with a mobile device.

FIG. 11 illustrates an example embodiment of a belt clip and protective case for a mobile device.

FIG. 12 illustrates an example embodiment of a belt clip and protective case with a mobile device.

FIGS. 13-21 illustrate an example embodiment of a protective case for a mobile device.

FIG. 22 illustrates an example embodiment of a protective case with a mobile device.

FIG. 23 illustrates an example embodiment of a protective case for a mobile device.

FIG. 24 illustrates an example embodiment of a protective case for a mobile device.

FIG. 25 illustrates cross-sectional views of an example embodiment of a protective case for a mobile device.

FIG. 26 illustrates an example embodiment of a protective case for a mobile device.

FIG. 27 illustrates an example embodiment of a belt clip and protective case for a mobile device.

FIG. 28 illustrates an example embodiment of a belt clip and protective case for a mobile device.

### DETAILED DESCRIPTION

In the following description, reference is made to the accompanying drawings, which form a part hereof. In the drawings, similar symbols typically identify similar components, unless context dictates otherwise. The illustrative embodiments described in the description and drawings are not meant to be limiting. Other embodiments may be utilized, and other changes may be made, without departing from the spirit or scope of the subject matter presented here. It will be readily understood that the aspects of the present disclosure, as generally described herein, and illustrated in the Figures, may be arranged, substituted, combined, and designed in a wide variety of different configurations, all of which are explicitly contemplated and made a part of this disclosure.

Further, the following description contains, by necessity, simplifications, generalization, and omissions of detail; consequently, those skilled in the art will appreciate that the description is illustrative only and is not intended to be in any way limiting. This description is not intended to identify key features or essential features of any subject matter described herein.

FIGS. 1 to 28 illustrate a protective case 2 that can provide protection against harsh conditions while also extending the battery life of a mobile device 4 with a back-up battery 6 built into the case 2. Durable protective cases 2 can have additional space to adequately protect the mobile device. This additional space can provide more than enough space to contain a rechargeable (e.g., lithium ion) battery 6 as, for example, illustrated in FIG. 3. The battery 6 can transmit and/or receive information and power to the mobile device 4 through an internal interface 8, as, for example, illustrated in FIGS. 3 and 4. The durable protective battery case 2 can transmit and receive information or power through an external interface 10 as, for example, illustrated in FIGS. 1, 2, 24, and 25. The internal interface 8 and the external interface 10 can be different connection types. The internal and external interfaces 8, 10 can comply to different standards. For example, the external interface 10 could be micro-USB while the internal interface 8 could be a Lightning connector or a 30-pin connector, both of which are frequently found on devices sold by Apple computers. The external interface 10 can allow for charging of the mobile device 4 and/or battery 6 and allow syncing with other devices or applications.

FIGS. 1-12 illustrate embodiments of the case 2 that include a rigid case portion 12 that provides crush-resistance surrounded by a malleable outer layer 14. In some embodiments, the rigid case portion 12 is comprised of multiple pieces as illustrated, for example, in FIGS. 4-6, 13-15, 18-21, and 26. The multiple pieces can connect including a gasket(s) (e.g., a first or main gasket) 16 as illustrated in FIGS. 4, 13, and 14 to maintain moisture resistance. As illustrated, for example, in FIG. 26, the case 2 can have a top cover 52 and a main housing 54. The main housing 54 can be waterproof and can be fully sealed. The top cover 52 and the main housing 54 can form the case 2, having a part line 56 between the top cover 52 and the main housing 54. The part line 56 can be fully sealed with a gasket 16 (sometimes referred to as a main gasket 16). The main gasket 16 can be over molded onto the rigid case portion 12 (e.g., the main housing 54). The main housing 54 can have a camera opening 58 for a camera 59 of the mobile device 4 as shown in FIG. 6. The camera opening 58 can have a film/mesh over the opening 58 for water and dust resistance. Referring to FIG. 4, the main housing 54 may comprise the battery as, for example, illustrated in FIGS. 3 and 25.

The rigid case portion 12 can include a gasket(s) (e.g., a second gasket) 17 to form a water-tight seal around a touch screen 26 of a mobile device 4. The gasket 17 can be over molded onto the rigid case portion 12 (e.g., the top cover 52). The rigid case portion 12 can include pass-through holes 18, as for example shown in FIG. 4, to allow access to controls and ports on the mobile device 4 (e.g., volume control 41, power button 51, mute switch 46, home button 24, micro-USB port, and headphone jack 42). The malleable outer layer 14 can be stretched over the rigid case portion 12 to provide impact-resistance and to increase water-resistance. The malleable outer layer 14 can include flexible port covers 19 corresponding to ports and/or buttons on the mobile device 4. In an embodiment, instead of a malleable outer layer, the rigid case portion 12 can include impact-absorbing regions 22, e.g., as illustrated in FIGS. 13-28. These impact-absorbing regions 22 can be overmolded to directly attach to the rigid case portion 12.

The case 2 can also allow access to controls on the front of a device 4, including buttons 24 and/or a touch screen 26, e.g., as illustrated in FIG. 5. The touch screen 26 can be protected either with a waterproof gasket 17 as illustrated, for example, in FIG. 3 or a membrane 28 as illustrated, for example, in FIG. 4, that allows inputs on the front of the membrane 28 to be passed through to the touch screen 26. In some embodiments, an inductive, capacitive, or tactile touchscreen 26 will register inputs through the membrane 28 without impedance.

As illustrated in FIGS. 1-28, the case 2 can have sensor cutouts or openings 30 for sensors of the mobile device 4. The sensor cutouts 30 can be internally sealed with mesh/film. The mesh/film (e.g., watertight material) can be on inside surfaces of the rigid case portion 12 to seal the cutouts/openings 30 such as, for example, a speaker port 31 and audio/microphone ports 33. The case can also have a noise canceling microphone port 37. The case 2 can have an over molded home button 32 for depressing the home button 24 of the mobile device 4. The case 2 can have two external interfaces 10. For example, as illustrated in FIG. 24, the case 2 can have a micro USB input 34 and charge pad input 36. The case 2 can have over mold pass through buttons 38 to access to controls and ports (e.g., the volume control 41) on the mobile device 4 as discussed herein. An auxiliary port 40 can provide access to a headphone jack 42 of the mobile device 4 shown in FIG. 4.

As illustrated in, for example, FIGS. 22 and 23, the case 2 can have a thin membrane area 44 for covering, for example, a mute switch 46 of the mobile device 4. The case 2 can have a rectangular opening 48 for the screen 26 of the mobile device 4 shown in FIG. 4. As illustrated in, for example, FIGS. 7 and 24, the case 2 can have a double injection pass through power button 50 for pressing a power button 51 of the mobile device 4 as shown in FIG. 4. As illustrated in FIG. 25, a wall of the rigid case portion 12 can be around the USB input port 34 to allow for the use of an O-ring type of gasket seal to provide water resistance as discussed herein.

FIGS. 7-12, 27 and 28 illustrate a belt clip 60 that can keep the case 2 securely on, for example, a hip of a user. In some embodiments, the case 2 can include a standby switch 62 to allow a user to choose when the battery 6 of the case 2 charges the mobile device 2. The case 2 can include light emitting diodes (LEDs) that indicate a remaining power of the battery 6. In some embodiments, the battery is rechargeable for over 500 full cycles, with partial charges not counting as full cycles. In some embodiments, the dimensions of the case can be 5.26 in×2.78 in×1.02 in. The battery capacity can be 2,500 mAh.

As discussed herein, the case 2 can include various features, such as a waterproof speaker cover, waterproof microphone cover, waterproof button, crush resistance, impact resistance, lithium ion batteries, LED indicators, NFC capabilities, NFC boost antenna (see e.g., U.S. Provisional Patent Application No. 61/696,139), three-part case, and/or clam-shell case design. The impact resistance can exceed military specifications (e.g., MIL-STD 810G). The embodiments discussed herein can offer splash and rain protection, sand and dust protection, impact and drop protection, and/or vibration and shock protection.

The foregoing description has set forth various embodiments of the systems and/or methods via the use of figures and/or examples. Insofar as such figures and/or examples contain one or more functions and/or operations, it will be understood by those within the art that each function and/or operation within figures or examples can be implemented individually and/or collectively. The herein described subject matter sometimes illustrates different components contained within, or connected with, different other components. It is to be understood that such depicted architectures are merely examples, and that in fact many other architectures can be implemented which achieve the same functionality. In a conceptual sense, any arrangement of components to achieve the same functionality is effectively “associated” such that the desired functionality is achieved. Hence, any two components herein combined to achieve a particular functionality can be seen as “associated with” each other such that the desired functionality is achieved, irrespective of architectures or intermedial components.

With respect to the use of substantially any plural and/or singular terms herein, those having skill in the art can translate from the plural to the singular and/or from the singular to the plural as is appropriate to the context and/or application. The various singular/plural permutations may be expressly set forth herein for sake of clarity.

It will be understood by those within the art that, in general, terms used herein, are generally intended as “open” terms (e.g., the term “including” should be interpreted as “including but not limited to,” the term “having” should be interpreted as “having at least,” the term “includes” should be interpreted as “includes but is not limited to,” etc.). It will be further understood by those within the art that if a specific number of an introduced embodiment recitation is intended, such an intent will be explicitly recited in the embodiment, and in the absence of such recitation no such intent is present. For example, as an aid to understanding, the disclosure may contain usage of the introductory phrases “at least one” and “one or more” to introduce embodiment recitations. However, the use of such phrases should not be construed to imply that the introduction of an embodiment recitation by the indefinite articles “a” or “an” limits any particular embodiment containing such introduced embodiment recitation to embodiments containing only one such recitation, even when the same embodiment includes the introductory phrases “one or more” or “at least one” and indefinite articles such as “a” or “an” (e.g., “a” and/or “an” should typically be interpreted to mean “at least one” or “one or more”); the same holds true for the use of definite articles used to introduce embodiment recitations. In addition, even if a specific number of an introduced embodiment recitation is explicitly recited, those skilled in the art will recognize that such recitation should typically be interpreted to mean at least the recited number (e.g., the bare recitation of “two recitations,” without other modifiers, typically means at least two recitations, or two or more recitations). Furthermore, in those instances where a convention analogous to “at least one of A, B, and C, etc.” is used, in general such a construction is intended in the sense one having skill in the art would understand the convention (e.g., “a system having at least one of A, B, and C” would include but not be limited to systems that have A alone, B alone, C alone, A and B together, A and C together, B and C together, and/or A, B, and C together, etc.). In those instances where a convention analogous to “at least one of A, B, or C, etc.” is used, in general such a construction is intended in the sense one having skill in the art would understand the convention (e.g., “a system having at least one of A, B, or C” would include but not be limited to systems that have A alone, B alone, C alone, A and B together, A and C together, B and C together, and/or A, B, and C together, etc.). It will be further understood by those within the art that virtually any disjunctive word and/or phrase presenting two or more alternative terms, whether in the description, embodiments, or drawings, should be understood to contemplate the possibilities of including one of the terms, either of the terms, or both terms. For example, the phrase “A or B” will be understood to include the possibilities of “A” or “B” or “A and B.”

Although the present subject matter has been described herein in terms of certain embodiments, and certain exemplary methods, it is to be understood that the scope of the subject matter is not to be limited thereby. Instead, the Applicant intends that variations on the methods and materials disclosed herein which are apparent to those of skill in the art will fall within the scope of the disclosed subject matter.

What is claimed is:

1. A protective enclosure for a mobile device with a touch screen, the protective enclosure comprising:
a first rigid case portion and a second rigid case portion that together form a protective shell around the mobile device, revealing the touch screen;
a first battery;
an internal interface capable of electrically coupling with the mobile device when the mobile device is in the protective enclosure;
a water-resistant seal between the first rigid case portion and the second rigid case portion; and
a flexible sleeve configured to be stretched around the protective shell.

2. The protective enclosure of claim 1, wherein the water-resistant seal is a first gasket.

3. The protective enclosure of claim 1, further comprising a plurality of openings and flexible port covers corresponding to ports and/or buttons on the mobile device.

4. The protective enclosure of claim 1, further comprising a second gasket capable of forming a water-tight seal around the touch screen.

5. The protective enclosure of claim 1, further comprising a membrane attached to the protective shell disposed in front of the touch screen.

6. The protective enclosure of claim 5, wherein an input on one side of the membrane opposite the touch screen will register with the touch screen on the mobile device when the mobile device is in the protective enclosure.

7. The protective enclosure of claim 1, further comprising a waterproof microphone port electrically coupled to a microphone port built into the mobile device.

8. The protective enclosure of claim 1, further comprising an external interface electrically coupled to the internal interface.

9. The protective enclosure of claim 1, wherein the first battery and a second battery in the mobile device are configured to be charged through the external interface.

10. The protective enclosure of claim 1, further comprising a battery information display.

11. The protective enclosure of claim 1, wherein the protective shell additionally comprises a third case portion.

12. The protective enclosure of claim 1, wherein the battery is enclosed within the first case portion.

13. A water-resistant protective enclosure for a mobile device with a touch screen, the protective enclosure comprising:
a first rigid case portion and a second rigid case portion that together form a protective shell with a plurality of openings corresponding to the ports and/or buttons of the mobile device, the protective shell revealing the touch screen;
a flexible sleeve configured to be stretched around the protective shell, the flexible sleeve comprising flexible port covers capable of sealing the plurality of openings;
a membrane attached to the protective shell disposed in front of the touch-screen, through which a tactile input on one side of the membrane will register with the touch screen on the mobile device;
a battery;
an internal interface capable of electrically coupling with the mobile device when the mobile device is in the protective enclosure;
an external interface electrically coupled to the internal interface; and
a water-resistant seal between the first rigid case portion and the second rigid case portion.

14. A water-resistant protective enclosure for a mobile device with a touch screen, the protective enclosure comprising:
a first case portion and a second case portion that together form a protective shell around the mobile device, revealing the touch screen;
a plurality of impact-absorbing regions fixed to the protective shell;
a battery;
an internal interface capable of electrically coupling with the mobile device when the mobile device is in the protective enclosure; and
a water-resistant seal between the first rigid case portion and the second rigid case portion.

15. The protective enclosure of claim 14, wherein the water-resistant seal is a first gasket.

16. The protective enclosure of claim 14, further comprising a plurality of openings and flexible port covers corresponding to ports and/or buttons on the mobile device.

17. The protective enclosure of claim 14, further comprising a second gasket capable of forming a water-tight seal around the touch-screen.

18. The protective enclosure of claim 14, further comprising a membrane attached to the protective shell disposed in front of the touch screen.

19. The protective enclosure of claim 18, wherein a tactile input on one side of the membrane will register with the touch screen on the mobile device.

20. The protective enclosure of claim 14, wherein the plurality of impact-absorbing regions are made of over-molded thermoplastic.

21. The protective enclosure of claim 14, further comprising a flexible sleeve configured to be stretched around the protective shell.

22. The protective enclosure of claim 14, further comprising an external interface electrically coupled to the internal interface.

23. The protective enclosure of claim 22, wherein the external interface is a different connection type from the internal interface.
